(19) United States
(12) Patent Application Publication
(10) Pub. No.: US 2005/0164469 A1
(43) Pub. Date: Jul. 28, 2005

(54) Method for N+ doping of amorphous silicon and polysilicon electrodes in deep trenches

(75) Inventor: Moritz Haupt, Dresden (DE)

Correspondence Address: SLATER & MATSIL LLP, 17950 PRESTON ROAD, SUITE 1000, DALLAS, TX, 75252, US

(73) Assignee: Infineon Technologies North America Corp., San Jose, CA (US)

(21) Appl. No.: 10/766,053

(22) Filed: Jan. 28, 2004

(51) Int. Cl. H01L 21/22; H01L 21/76; H01L 21/38

(52) U.S. Cl. 438/434; 438/433; 438/430; 438/561; 438/564

(57) ABSTRACT

The present invention related to doping of amorphous silicon and polysilicon in trench structures for semiconductor devices. A single gas phase doping step is performed after a thin layer of amorphous silicon or polysilicon is deposited in the trench. The gas phase doping occurs at elevated temperature and moderate pressure to yield a dopant concentration on the order of 1×10²⁰ atoms/cm³.

### BACKGROUND OF THE INVENTION

The present invention relates to semiconductor fabrication. More particularly, the present invention relates to a method of achieving a high dopant concentration in a semiconductor material by means of a streamlined doping process.

Semiconductor devices are employed in various systems in a wide variety of applications. For example, one important type of semiconductor device is known as dynamic random access memory (“DRAM”). DRAM is extensively used for memory in computers and other electronic devices. A basic DRAM memory cell typically includes one capacitor and one transistor, which may be formed in a semiconductor substrate. The capacitor stores a charge that can represent a data value. The transistor allows the data value to be refreshed, read from or written to the capacitor.

FIG. 1 illustrates a schematic diagram of a conventional DRAM memory cell 100 comprising a capacitor 110 and a transistor 120. The capacitor 110 includes a first electrode 112 and a second electrode 114, which are separated by a dielectric material (not shown), as is known in the art. The transistor 120 includes a source (or drain) 122 connected to the second electrode 114. The transistor 120 also includes a drain (or source) 124 connected to a bitline 132, as well as a gate 126 connected to a wordline 130. The data value may be refreshed, read from or written to the capacitor 110 by applying appropriate voltage to the bitline 132 and/or the wordline 130.

Typically, thousands or hundreds of thousands of devices, e.g. DRAM memory cells, are manufactured simultaneously as part of a single semiconductor wafer. The manufacturing process may include multiple steps of, for example, depositing material on the substrate, removing selected portions of the material, doping the material and cleaning. Material may be deposited in layers and/or connected with other portions of the substrate using, e.g., metal-based lines and vias.

A series of DRAM memory cells is typically arranged in an array. More DRAM cells can fit onto a chip by reducing the size of the capacitor and/or the transistor, thus resulting in greater memory capacity for the chip. One method of minimizing the size of a DRAM cell is to reduce the surface area of the device, which may be accomplished by vertically constructing .the components, i.e., where a semiconductor device includes components formed in several layers. One method of performing vertical construction involves stacking layers of material that form the capacitor and/or the transistor on the surface of a semiconductor substrate.

An alternative vertical construction method forms components in a trench in the semiconductor substrate. For example, a dopant may be added to portion of the substrate surrounding the trench in order to form a first one of the electrodes, the “outer electrode” or “buried plate” of the capacitor. A dielectric film or “node dielectric” may then be deposited along the sidewalls of the trench. Then, polycrystalline silicon (“polysilicon” or “poly-Si”) or amorphous silicon (“a-Si”) may be deposited on the node dielectric, to act as the second electrode, the “inner electrode” or “storage electrode” of the capacitor. Poly-Si is a form of silicon having a short-range crystalline structure, i.e., the silicon has multiple crystalline cells arranged in a random manner. A-Si has a microcrystalline structure (e.g., deposited at temperatures below about 600° C.) where the crystalline grains have a size on the order of tens to hundreds of angstroms. Poly-Si (e.g. deposited at about 625° C.) has a grain size of about 0.1 μm with a columnar grain structure. The transition from the a-Si state to the poly-Si state depends on the process conditions such as temperature, deposition pressure and impurity or dopant incorporation/concentration. A third type of silicon, known as epitaxial silicon (“epi-Si”) has a single continuous crystalline structure. Epi-Si is not usually employed in deep trench structures because it does not form properly in the trench. Once the inner electrode is formed, further processing steps may then be employed in order to finish fabricating the capacitor and/or other components of the memory cell. This may include, e.g., forming a buried strap connection to the transistor or connections to the bitline or wordline of the memory cell.

In one technique, trenches may be formed relatively deep into the substrate (“deep trenches”), for example between 4-8 μm below the substrate surface. This will permit the total size of the trench to remain the same, or even increase, when compared to a shallower but wider trench. FIG. 2 illustrates a conventional DRAM memory cell 200 comprising a transistor 210 and a trench capacitor 260. The transistor 210 includes a gate 212 as well as source/drain diffusion regions 214 and 216 separate by a channel 218. The gate 212 is connected to a wordline 220 aligned along a plane directed into the page. The source or drain 216 is connected to a bitline 284 through a contact 282. The trench capacitor 260 is formed in substrate 202. As used herein, when the term “in” is used in relation to the substrate, it includes, but is not limited to, forming a component or feature on or within the substrate, whether or not in direct physical contact with the substrate material. The trench capacitor 260 includes a buried plate 262 partly surrounding sidewalls 261, a node dielectric 264 and an inner electrode 266. A buried strap 225 connects the transistor 210 to the trench capacitor 260. An insulating collar 268 prevents leakage current between the buried strap 225 and the buried plate 262. A buried well 270 may also be provided to connect the buried plates 262 of an array of DRAM memory cells 200. An insulating layer 288 provides isolation between various contacts, and shallow trench isolation 280 may be used to isolate adjacent DRAM memory cells 200.

Deep trenches having a small surface area are typically said to have a high aspect ratio. The “aspect ratio” is the ratio of the depth of a trench compared to the width of the trench. For example, memory cells fabricated as part of a 256 Mbyte DRAM chip may include capacitor trenches having an aspect ratio of between 10:1 and 20:1. This means that the depth of the trench walls is between 10 and 20 times greater than the width of the trench. In higher density DRAM chips, such as chips of 1 Gbyte or more, a typical deep trench aspect ratio may be on the order of 40:1 to 60:1 or higher. In such high aspect ratio situations, the trenches are typically very narrow. For example, as can be seen in FIG. 2, the trench capacitor 260 has a high aspect ratio, wherein width W is substantially less than high H. The very narrow trench width W impacts not only the thickness of the fill material of the inner electrode 266 of the trench capacitor 260, but also how the fill material is formed. A material thin enough to fit into the trench must still have properties suitable for an inner electrode, such as low resistivity and high capacitance. Typical resistivity values for the electrode are on the order of 1 mΩcm. The capacitance should be at least 25 fF/cell. If the capacitance falls below this level, the charge of the capacitor may dissipate too rapidly and the data value stored by the memory cell may be lost. Thus, together with suitable capacity enhancement methods, a capacity value of 35 fF/cell (or higher) should be maintained. Thus, in order to properly fabricate a high aspect ratio deep trench capacitor, unconventional materials and processes of fabricating the materials may be required.

In conventional processing, an inner electrode of poly-Si or a-Si may be produced by some form of Chemical Vapor Deposition (CVD) at sub-atmospheric or reduced pressure, e.g., Low Pressure CVD (LPCVD). Conventional deposition conditions to process a-Si are based on the dissociation of silane (SiH₄) at a temperature between 500 and 550° C. and a partial pressure of 600-1000 mTorr. These conditions will form an approximate amorphous layer of 8 to 20 nm. Further dilution of the SiH₄ with H₂ might be necessary. As mentioned above, the major parameters for determining the amorphous state or polycrystalline state are deposition temperature, pressure and SiH₄ concentration. Poly-Si is obtained at a temperature of about 620° C., while maintaining the other process parameters as with the amorphous deposition. In deep trenches, the narrow width of the sidewalls poses an important problem, as discussed earlier. This problem will even more pronounced as shrinking ground rules (feature sizes of components) force even more narrow trench designs.

Dopants are often added to the inner electrode in order to increase its conductivity, i.e., the ability of the electrode to conduct electricity. A method of doping the inner electrode is to apply a layer of a-Si or poly-Si to the node dielectric lining the trench sidewalls, followed by “soaking” dopant into the a-Si or poly-Si. The a-Si or poly-Si is typically on the order of 8-20 nm, depending on the groundrule or size of the deep trench. For example, in a trench having a depth of 6 μm having an aspect ratio of 60:1, the width of the trench is 100 nm (0.1 μm) . The minimum thickness of the first undoped a-Si or poly-Si layer is the limiting factor for the number of doping soaking steps which can be brought into the deep trench. The doping or soaking process is carried out at suitable pressures in the LPCVD furnace or CVD system.

In CVD processing, a chemical containing the material to be deposited (e.g., dopant) reacts with another chemical to release the material. The material is deposited while reaction by-products are removed from the chamber. LPCVD, as mentioned above, is a variation of CVD in which the chemical reaction occurs at low pressure. For example, the LPCVD process is performed with a pressure significantly less than 5 Torr, such as between 100-1000 mTorr. When arsenic (As) is used as the dopant, a conventional process may flow arsine gas (AsH₄) at values around 50 sccm and SiH₄ at 120 sccm, while the temperature is in the range of 500-550° C.

The steps of depositing the a-Si or poly-Si layer followed by soaking often must be repeated 2-4 times in order to achieve a dopant concentration of at least 7 to 9×10¹⁹ atoms/cm³. FIG. 3 illustrates a secondary ion mass spectroscopy (SIMS) junction profile 300 plotting dopant concentration versus depth when the conventional soaking process is employed. In this case a three soaking step process has been employed. As can be seen from line 302, the LPCVD three-soak process results in an arsenic concentration of approximately 8.1×10¹⁹ atoms/cm³ down to a depth of about 6 μm.

One problem with this layering scheme in a high aspect ratio trench or otherwise narrow-width trench is the overall thickness of the inner electrode when compared to the width of the trench. For example, a three-layer process would result in at least 24-60 nm of a-Si or poly-Si on each sidewall of the trench. This can “clog” or even exceed the width of the trench in a small feature size and/or high aspect ratio trench. Therefore, a need exists for improved doping of the inner electrode such that the a-Si or poly-Si fill material does not clog the trench or exceed the width of the trench, while still achieving a dopant concentration of at least about 1×10¹⁹ atoms/cm³. A need also exists for improved methods of forming the fill material with a high concentration of uniformly distributed dopant therein.

### SUMMARY OF THE INVENTION

In accordance with an embodiment of the present invention, a method of fabricating a semiconductor device in a substrate is provided. The method includes forming a trench in the substrate. The trench is defined by sidewalls. Next, a silicon layer is formed along the sidewalls to continuously cover at least a portion of the sidewalls. The silicon layer is selected such that it does not have a continuous crystalline structure. Then gas phase doping is performed to dope the silicon layer. The dopant has a concentration of at least 1×10¹⁹ atoms/cm³. Preferably, the silicon layer is either polysilicon or amorphous silicon. The silicon layer is preferably at least 8 nm thick. In one alternative, the gas phase doping is performed at a temperature between about 850-1000° C., and the silicon layer is formed at a temperature less than the gas phase doping. In another example, the gas phase doping pressure is between about 1-100 Torr. The dopant is preferably arsenic or phosphorous. When the dopant is arsenic, the dopant precursor gas is preferably AsH₄.

In a further example, the gas phase doping is performed at a temperature between 850-950° C. and a pressure of between 15-30 Torr. In this example, the dopant is preferably arsenic formed using an AsH₃ precursor. The precursor may be flowed at a rate of 100-300 sccm in the presence of H₂ or He for between 5-120 minutes. In yet another alternative, forming the silicon layer and performing gas phase doping comprise an in-situ process. In another alternative, forming the silicon layer and performing gas phase doping comprise an ex-situ process. In the ex-situ process, a wet clean of the substrate may be performed prior to gas phase doping. The wet clean is used to remove a native oxide on the silicon layer. In yet another alternative, the method further comprises substantially filling the trench with a fill material after performing the gas phase doping.

In accordance with another embodiment of the present invention, a method of fabricating a semiconductor device in a substrate is provided. The method includes first forming a trench having sidewalls in the substrate. Next, the sidewalls are lined with a node dielectric. Then, a silicon layer is deposited over the node dielectric such that the silicon layer continuously covers at least a portion of the node dielectric. The silicon layer does not have a continuous crystalline structure. Then gas phase doping is performed in a reaction chamber. The gas phase doping includes flowing a dopant precursor gas in the reaction chamber at a rate of between 100-300 sccm. The reaction chamber is heated to a temperature of between 850-1000° C. during the doping. The reaction chamber is pressurized at between 1-100 Torr during doping. The result of the gas phase doping is having the silicon layer doped with a dopant having a concentration of at least 1×10¹⁹ atoms/cm³.

The method may further comprise substantially filling the trench with amorphous silicon after performing the gas phase doping. In an example, the silicon layer may comprise either amorphous silicon or polysilicon. Preferably, the silicon layer is at least 8 nm thick. The dopant is preferably either arsenic or phosphorous. In further examples, depositing the silicon layer and performing the gas phase doping may comprise either an in-situ or an ex-situ process. When an ex-situ process is employed, the method may further include performing a wet clean of the substrate before performing the gas phase doping. The wet clean removes a native oxide on the silicon layer. In this case, the dopant preferably has a concentration of at least 5×10¹⁹ atoms/cm³.

In accordance with yet another embodiment of the present invention, a method of fabricating a semiconductor device in a substrate is provided. The method comprises forming a transistor in a first region of the substrate and a trench capacitor in a second region of the substrate, wherein the transistor and the trench capacitor are electrically connected to form a memory cell. The trench capacitor is fabricated by first forming a trench having sidewalls in the second region of the substrate. A buried plate is formed in the substrate adjacent to a portion of the sidewalls. The sidewalls are lined with a node dielectric. The process deposits a silicon layer to continuously cover at least a portion of the node dielectric. The silicon layer does not have a continuous crystalline structure. Gas phase doping of the silicon layer is then performed so that the silicon layer has a dopant concentration of at least 1×10¹⁹ atoms/cm³. The doped silicon layer comprises an inner electrode, and the inner electrode, the node dielectric and the buried plate comprise the trench capacitor.

### BRIEF DESCRIPTION OF THE DRAWINGS

FIG. 1 illustrates a schematic diagram of a conventional DRAM memory cell.

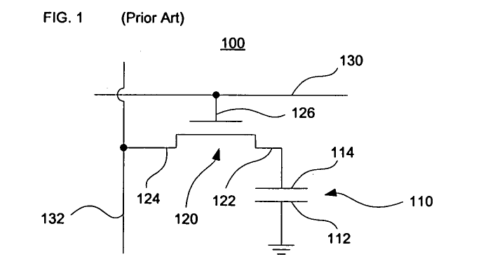

FIG. 2 illustrates a cross-sectional view of a DRAM memory cell having a trench capacitor.

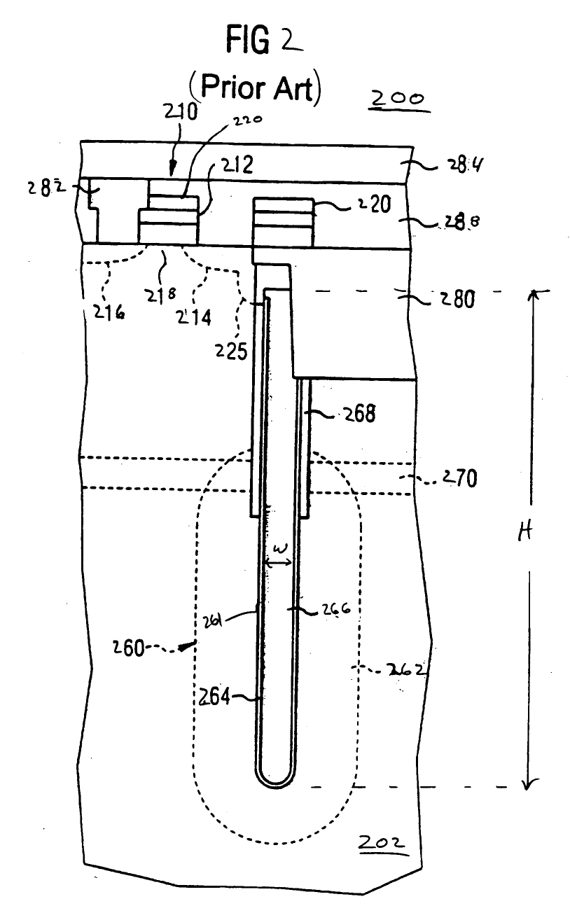

FIG. 3 illustrates a chart of dopant concentration versus depth in a conventional trench doping process.

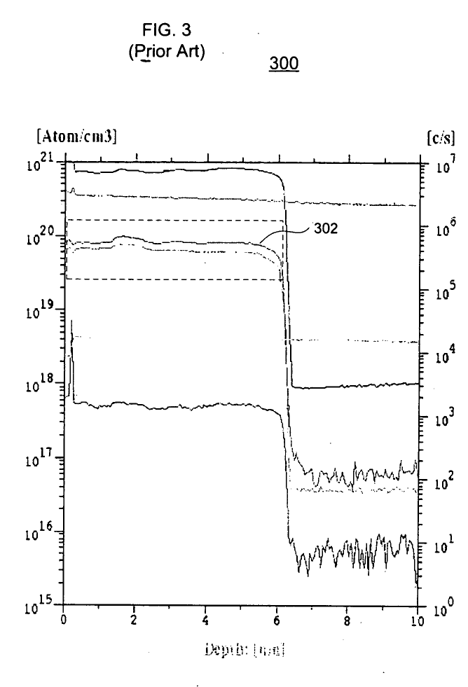

FIGS. 4A-C are schematic cross-sectional views illustrating steps in the formation of an electrode according to aspects of the present invention.

FIG. 5 illustrates a chart of dopant concentration versus depth according to a method of the present invention.

FIGS. 6A-B illustrate temperature versus time profiles comparing conventional processing with a method of the present invention.

### DETAILED DESCRIPTION

The present invention provides an enhanced doping process suitable for deep trench devices, although the invention may be used in, for example, other trench configurations and related structures. The materials and processes described below can be employed with various kinds of substrates, including, but not limited to silicon (Si), gallium arsenide (GaAs), indium phosphide (InP), and silicon carbide (SiC). It is to be appreciated that certain steps may be performed in different order, and that the numbers used, e.g., temperature, flow rate and pressure, are approximations and may be varied.

The present invention uses a single Gas Phase Doping (GPD) step to dope a-Si or poly-Si in a trench structure formed in a semiconductor substrate. The single GPD step replaces the repeated soaking steps of prior processes. GPD is a high temperature process on the order of 850-1100° C. utilizing process pressure between 10 to 300 Torr (process pressures up to atmospheric pressure are also possible). With this set of conditions the number of dopant atoms is high, resulting in high doping concentrations. In principle, the dopant is introduced into the chamber of a LPCVD or CVD reactor through suitable inlets or injectors. The dopant (As or P) is adsorbed onto the a-Si surface and incorporated into the lattice structure through diffusion. For the examples described herein, GPD carried out at high pressures provides the highest amount of doping atoms possible into high aspect ratio trench structures. Together with the thin layers of a-Si or poly crystalline, a desired low resisitivity fill is achieved.

GPD has been used in the past for various doping procedures. For example, GPD has been used to dope a shallow channel in the substrate between the source and drain in a transistor, as described in U.S. Pat. No. 5,866,472 to Moslehi, which is herein incorporated by reference. Another use of GPD is to perform arsenic doping in a low pressure reactor as described in U.S. Pat. No. 6,413,844 to Beulens et al., which is herein incorporated by reference. GPD has also been used to dope epi-Si to form a buried plate in a trench capacitor, as described in U.S. Pat. No. 5,945,704 to Schrems et al., and U.S. Pat. No. 6,528,384 to Beckmann et al., which are herein incorporated by reference.

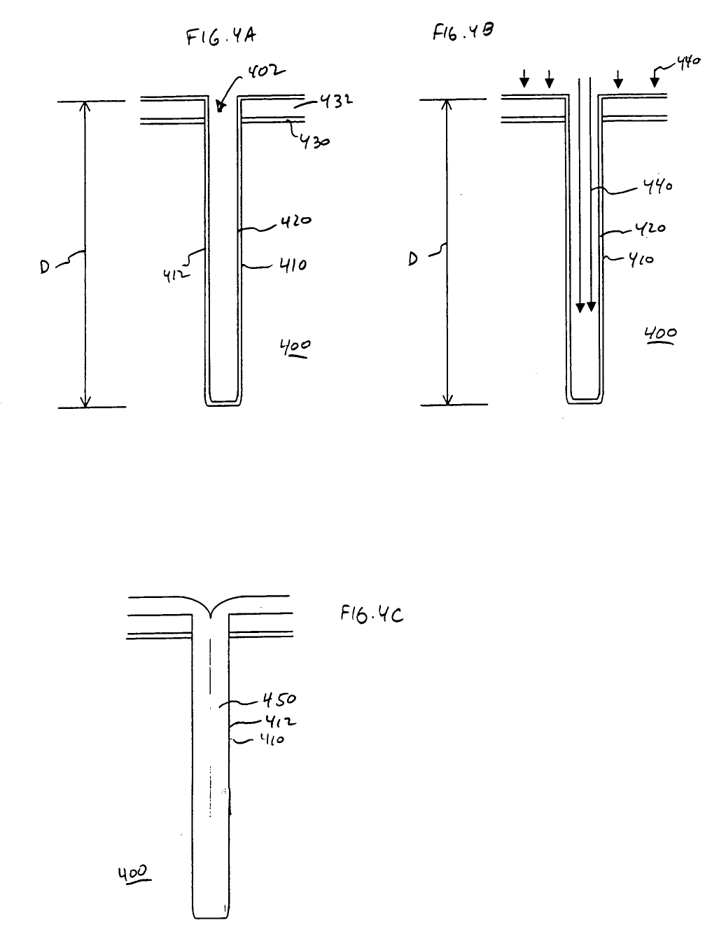

However, GPD has not been used for doping a-Si or poly-Si during formation of a trench structure, such as an inner electrode in a trench capacitor. FIGS. 4A-C illustrate a preferred doping method according to the present invention. FIG. 4A is a cross-sectional view of a trench 402 formed in a semiconductor substrate 400. Certain components (e.g., the buried plate) have been omitted for the sake of clarity. The trench 402 has a depth D, preferably on the order of 6-8 μm. In actuality, the trench 402 is a three-dimensional structure defined by sidewalls 412 which may have a cylindrical or other shape. A pad oxide 430 and/or a pad nitride 432 may be formed at the surface of the substrate adjacent to the trench 402. A node dielectric 420 lines at least a portion of the sidewalls 412. The node dielectric 420 may be any suitable dielectric material, preferably having a high dielectric constant, i.e., “high K.” As used herein, “high K” materials have a dielectric constant greater than silicon dioxide (SiO₂), which has a dielectric constant of approximately 3.9. By way of example only, one suitable dielectric material is tantalum pentoxide (Ta₂O₅)

A layer 420 of a-Si or poly-Si is deposited or otherwise formed over the node dielectric 412. For example, the layer 420 may be deposited by a CVD or equivalent process such that the layer 420 provides continuous coverage over the node dielectric 412. The continuous coverage need not completely cover the node dielectric 412; however, the covered portion should be continuously covered (e.g., contiguous). The layer 420 should be at least about 8 nm thick, although more preferably at least 10 nm thick to ensure there are no islands or other discontinuities in the coverage. Process conditions for this thin layer deposition are, for example, 500° C., 600-1000 mTorr, and total gas SiH₄ flows at the top and bottom of the chamber are 200-400 sccm. The deposition rate is preferably in the range of 0.5 to 1 nm/min. For a closed a-Si layer (e.g., no holes) a low deposition temperature is a prerequisite..

Next, as shown in FIG. 4B, GPD is performed as shown by arrows 440. By way of example only, an n-type dopant such as arsenic or phosphorous may be employed, although the invention is capable of using other n-type species as well as p-type species. An exemplary process will now be described using arsenic as the dopant. GPD preferably occurs in a temperature range of between about 850-1000° C. More preferably, the temperature is between 850-950° C. The pressure may range between 1-100 Torr. Preferably, the pressure is between 15-30 Torr. An arsenic precursor, such as AsH₃, is flowed at a rate of between 100-300 sccm, which may occur in the presence of hydrogen (H₂) or helium (He). More preferably, AsH₃ is flowed at 300 sccm. Dopant gases for arsenic, phosphorous and other dopants are well known in the art. This process may take between 5-120 minutes, depending on the other process conditions and the desired dopant concentration. Preferably, the time is between 30-120 minutes.

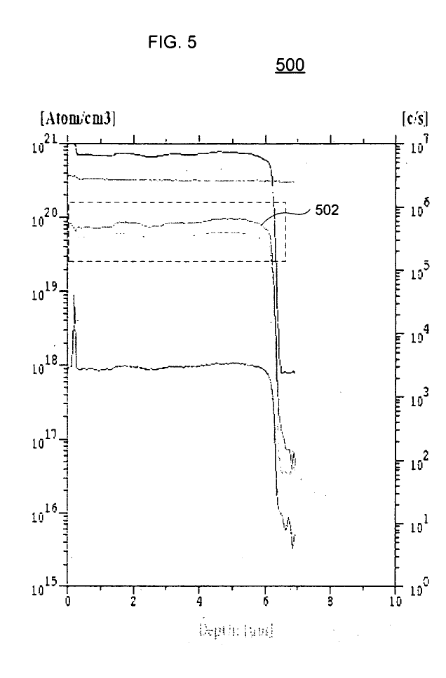

FIG. 5 illustrates the resulting dopant concentration as part of a top-down SIMS junction profile 500 plotting dopant concentration versus depth when the GPD process is employed. As can be seen from line 502, the single pass GPD process results in an arsenic concentration of approximately 9.6×10¹⁹ atoms/cm³ down to a depth of about 7 μm. The dopant is substantially uniformly distributed through the material.

FIG. 4C illustrates an optional subsequent step wherein a material 450 such as a-Si is formed within the trench 402, thereby completing formation of the inner electrode. Preferably, the material 450 is deposited in the trench to substantially fill it. The filling-layer-step is mainly performed after the complete layer and soaking/GPD steps have been carried out to provide low resistivity (e.g., high doping concentration) in the order of 1 mΩcm. Thus, most of the deep trench is already filled, especially with respect to the bottom part. However, the last intrinsic a-Si deposition step is necessary to ensure a complete fill for the following structuring of, e.g., the collar isolation. This last deposition step may be carried out at a much higher deposition rate than the earlier deposition(s).

The process described above with regard to FIGS. 4A-C may be performed using conventional LPCVD reaction equipment (e.g., a reaction chamber). Furthermore, because the GPD process of the present invention can employ conventional equipment, the process may occur either ex-situ or in-situ. In the in-situ process, the wafer or batch of wafer (if a batch reactor is used) remains in the LPCVD chamber for the GPD phase of the process subsequent to the a-Si or poly-Si formation.

The ex-situ process may involve first performing the a-Si or poly-Si deposition in a LPCVD chamber, for example. Then, the wafer or batch of wafers can be removed from the chamber and the GPD doping may be performing separately. Note that a thin native oxide may form on the surface of the wafer when it is removed from the LPCVD chamber and exposed to ambient air. The native oxide can retard the doping process. In order to overcome this problem, suitable pre-cleaning may be performed. For example, the wafer may be subject to a wet clean of, e.g., hydrofluoric acid (HF), buffered hydrofluoric acid (BHF) or dilute hydrofluoric acid (DHF) as is known in the art. It is advantageous to perform the ex-situ process with a fixed time coupling of 2 and 4 hours to reduce the growth of a native oxide between the a-Si/poly-Si deposition step and the doping step.

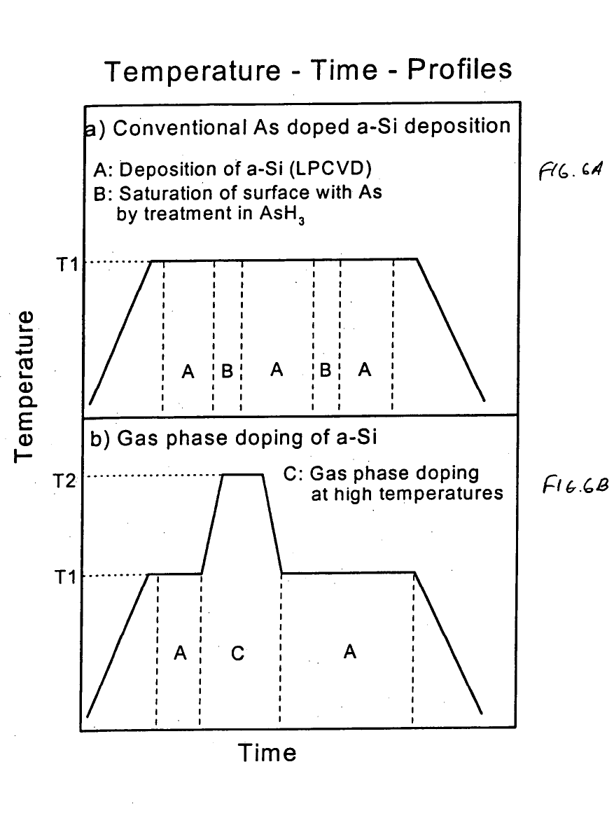

Thus, it can be seen that the present invention achieves a high doping concentration on the order of 1×10²⁰ atoms/cm³ without the extra processing steps of past procedures. Furthermore, the doped inner electrode of the present invention is much thinner than in the past because repeated layering steps are avoided, thus giving enough extendibility for future technology generations with respect to capacitor (or other device) formation utilizing a deep trench. FIGS. 6A-B illustrate several key differences between conventional LPCVD doping as compared with the GPD doping of the present invention. As seen in FIG. 6A, conventional arsenic doping of a-Si using LPCVD takes place at a single temperature T1. Multiple layers of a-Si (“A”) are sandwiched by repeated soaking with an arsenic precursor (“B”) . In contrast, in FIG. 6B, GPD occurs at an elevated temperature T2, which as described earlier is preferably between about 850-1000° C.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A method of fabricating a semiconductor device in a substrate, the method comprising:
forming a trench having sidewalls in the substrate;
forming a silicon layer along the sidewalls of the trench to continuously cover at least a portion of the sidewalls, the silicon layer not having a continuous crystalline structure; and
performing gas phase doping so that the silicon layer is doped with a dopant having a concentration of at least 1×10¹⁹ atoms/cm³.

2. The method of claim 1, wherein the silicon layer comprises amorphous silicon.

3. The method of claim 1, wherein the silicon layer comprises polysilicon.

4. The method of claim 1, wherein the silicon layer is at least 8 nm thick.

5. The method of claim 1, wherein the gas phase doping is performed at a temperature between about 850-1000° C., and forming the silicon layer is performed at a temperature less than the gas phase doping.

6. The method of claim 1, wherein the gas phase doping is performed at a pressure of between 1-100 Torr.

7. The method of claim 1, wherein the dopant is arsenic.

8. The method of claim 7, wherein the gas phase doping uses AsH₃ as a dopant precursor.

9. The method of claim 1, wherein the dopant is phosphorous.

10. The method of claim 1, wherein the gas phase doping is performed at a temperature between 850-950° C. and a pressure of between 15-30 Torr.

11. The method of claim 10, wherein the dopant is arsenic formed by an AsH₃ precursor.

12. The method of claim 11, wherein the precursor is flowed at a rate of 100-300 sccm in the presence of H₂ for between 5-120 minutes.

13. The method of claim 11, wherein the precursor is flowed at a rate of 100-300 sccm in the presence of He for between 5-120 minutes.

14. The method of claim 1, wherein forming the silicon layer and performing the gas phase doping comprise an in-situ process.

15. The method of claim 1, wherein forming the silicon layer and performing the gas phase doping comprise an ex-situ process.

16. The method of claim 15, further comprising performing a wet clean of the substrate before performing the gas phase doping, wherein the wet clean removes a native oxide on the silicon layer.

17. The method of claim 1, further comprising substantially filling the trench with a fill material after performing the gas phase doping.

18. A method of fabricating a semiconductor device in a substrate, the method comprising:
forming a trench having sidewalls in the substrate;
lining the sidewalls with a node dielectric;
depositing a silicon layer to continuously cover at least a portion of the node dielectric, the silicon layer not having a continuous crystalline structure; and
performing gas phase doping in a reaction chamber by:
flowing a dopant precursor gas in the reaction chamber at a rate of between 100-300 sccm,
heating the reaction chamber to a temperature of between 850-1000° C., and
pressurizing the reaction chamber to a pressure of between 1-100 Torr, wherein the gas phase doping results in the silicon layer being doped with a dopant having a concentration of at least 1×10¹⁹ atoms/cm³.

19. The method of claim 18, further comprising substantially filling the trench with amorphous silicon after performing the gas phase doping.

20. The method of claim 18, wherein the silicon layer comprises amorphous silicon.

21. The method of claim 18, wherein the silicon layer comprises polysilicon.

22. The method of claim 18, wherein the silicon layer is at least 8 nm thick.

23. The method of claim 18, wherein the dopant is arsenic or phosphorous.

24. The method of claim 18, wherein depositing the silicon layer and performing the gas phase doping comprise an in-situ process.

25. The method of claim 18, wherein depositing the silicon layer and performing the gas phase doping comprise an ex-situ process.

26. The method of claim 25, further comprising performing a wet clean of the substrate before performing the gas phase doping, wherein the wet clean removes a native oxide on the silicon layer.

27. The method of claim 26, wherein the dopant has a concentration of at least 5×10¹⁹ atoms/cm³.

28. A method of fabricating a semiconductor device in a substrate, the method comprising:
fabricating a transistor in a first region of the substrate;
forming a trench having sidewalls in a second region of the substrate;
forming a buried plate in the substrate adjacent to a portion of the sidewalls;
lining the sidewalls with a node dielectric;
depositing a silicon layer to continuously cover at least a portion of the node dielectric, the silicon layer not having a continuous crystalline structure;
performing gas phase doping of the silicon layer so that the silicon layer has a dopant concentration of at least 1×10¹⁹ atoms/cm³, the doped silicon layer comprising an inner electrode, wherein the buried plate, the node dielectric and the inner electrode comprise a trench capacitor; and
electrically connecting the trench capacitor to the transistor to form a memory cell.
